(19) United States
(12) Patent Application Publication
(10) Pub. No.: US 2024/0274399 A1
(43) Pub. Date: Aug. 15, 2024

(54) Device For Interfacing A Sample Transfer Device To An Analytic Or Sample Preparation Device And A Container For Transporting A Sample Under Environmentally Controlled Conditions

(71) Applicant: Ferrovac AG, Zürich (CH)

(72) Inventors: Urs MAIER, Zürich (CH); Claudio WEISS, Baar (CH)

(21) Appl. No.: 18/574,428

(22) PCT Filed: Jul. 2, 2021
(86) PCT No.: PCT/EP2021/068404

§ 371 Date: Dec. 27, 2023

(51) Int. Cl. H01J 37/18; H01J 37/28; H01J 37/30

(52) U.S. Cl. CPC H01J 37/185; H01J 37/28; H01J 37/30; H01J 2237/184; H01J 2237/204; H01J 2237/31749

(57) ABSTRACT

The present invention relates to a device (100,300) for interfacing a sample transfer device (200) to an analytic or sample preparation device comprising a loading chamber (101), wherein the loading chamber comprises a first port (105) for attaching the device to the analytic device or the sample preparation device and a second port (106) for attaching a sample transfer device, wherein the device (100,300) comprises an insertion opening (104) for inserting a sample kept under atmospheric condition into the loading chamber (101) and a closure element (102) removable from the insertion opening, wherein the insertion opening exhibits a quick-locking mechanism (103) with which the insertion opening can be scaled with the closure element, wherein the device comprises a gate valve (108) attached to the first port (105), wherein the gate valve comprises a pumping port (108a) for evacuating the loading chamber (101) and a venting port (108b) for venting the loading chamber (101). The present invention relates also to a container (400, 500, 600, 700) for transporting a sample under vacuum or inert gas atmosphere.

### TECHNICAL FIELD

The present invention relates to the technical field of device for the transfer of samples to analytic or sample preparation devices. More precisely, the present invention relates to a device for interfacing a sample transfer device to an analytic or sample preparation device allowing for the transfer of the sample under environmentally controlled conditions, in particular inert gas atmosphere or vacuum conditions. The present invention also concerns a container for transporting a sample under inert gas atmosphere or under vacuum that be used in combination with the interfacing device of the present invention or in combination with another interfacing device.

### BACKGROUND OF THE INVENTION

As applying complementary analytical methods to the same sample is becoming increasingly important in fundamental research, material science and biology, it is of great significance that the environment of the sample is ultimately controlled in terms of atmosphere and temperature during the whole work flow of a planned experiment. Under these premises an Ultrahigh Vacuum Cryo Transfer Module (UHVCTM) has become a key component in establishing such an environmentally controlled workflow. Such a UHVCTM is for instance presented in the international application WO2020119956A1 and allows for keeping a sample at a vacuum level of 10⁻¹¹ mbar and at a temperature below 130K and for transferring this sample to an analytic chamber, such as for instance a scanning tunneling microscope or an electron microscope.

However, each independent instrument involved in the experimental workflow needs a device to which a transfer device, such as a UHVCTM, can be easily attached and which allows for transferring a sample from the transfer device to the position in the instrument where the analysis takes place while environmental control of the sample is not compromised.

While interfacing modules that allow for interfacing a transfer device to an analytic chamber are known in the art, such modules do not allow for transferring a sample kept in vacuum from the transfer device to the analytic chamber and to insert a sample directly into the interfacing device in order to be able to introduce the sample in the analytic chamber also from atmosphere.

Such a module would have the advantage that it can be kept mounted on a port of the analytic chamber while allowing for the introduction in this chamber of a sample kept under vacuum condition or directly from atmosphere.

It is therefore a goal of the present invention to propose an interfacing device that permits to solve the problems mentioned above.

### SUMMARY OF THE INVENTION

Thus, the object of the present invention is to propose a novel device for interfacing a sample transfer device to an analytic or sample preparation chamber, with which the above-described drawbacks of the known systems are completely overcome or at least greatly diminished.

An object of the present invention is in particular to propose an interfacing device that allows for the insertion of a sample kept at atmospheric or vacuum conditions into an analytic or sample preparation chamber.

An object of the present invention is also to propose a novel container that permits the transport of a sample kept in an inert gas atmosphere or under vacuum conditions.

According to the present invention, these objects are achieved in particular through the elements of the two independent claims. Further advantageous embodiments follow moreover from the dependent claims and the description.

In particular, the objects of the present invention are achieved by a device for interfacing a sample transfer device to an analytic or sample preparation device comprising a loading chamber, wherein the loading chamber comprises a first port for attaching the device to the analytic device or the sample preparation device and a second port for attaching a sample transfer device, wherein the device comprises an insertion opening for inserting a sample from atmospheric condition into the loading chamber and a closure element removable from the insertion opening, wherein the insertion opening exhibits a quick-locking mechanism with which the insertion opening can be sealed with the closure element and wherein the device comprises a gate valve attached to the first port, and wherein the gate valve comprises a pumping port for evacuating the loading chamber and a venting port for venting the loading chamber.

Such an interfacing device allows for transferring a sample kept at atmospheric pressure, for instance in air or an inert gas atmosphere, through the insertion opening of the loading chamber or kept under vacuum conditions inside a vacuum transfer device, such as an ultra-high vacuum transfer device, attached to the loading chamber.

By means of the gate valve comprising a pumping port and a venting port, it is possible to minimize the volume of the loading chamber and therefore minimize the pumping time required to bring the pressure inside the loading chamber to an acceptable level for transferring the sample to the analytic chamber or to the vacuum transfer device. Since the transfer time, including the pumping time, is crucial in a number of experiments since sample must be transferred as quickly as possible in order to avoid deterioration, the interfacing device according to the present invention represents a big improvement compared to the devices known from the state-of-the-art.

It is important to note that the interfacing device is not only advantageous to transfer a sample to the analytic chamber but also to the vacuum transfer device. Indeed, a sample prepared for instance at atmospheric conditions can be inserted into the loading chamber which is subsequently evacuated to allow for transferring the sample into the vacuum transfer device.

Thus the interfacing device according to the present invention can be permanently mounted to an analytic or preparation chamber, for instance a dual beam instrument, i.e. a scanning electron microscope combined with a focused ion beam, since it allows for transferring a sample from atmospheric pressure or vacuum conditions. The interfacing device does thus not need any more to be replaced depending on the conditions under which the sample is kept.

Advantageously, the insertion opening and the quick-lock mechanism are arranged such that the insertion opening can be sealed with only one hand.

In a first preferred embodiment of the present invention, the quick-locking mechanism comprises a bulkhead rotating clamp with which the closure element can be pushed against a gasket of the insertion opening. Such quick-locking mechanism allows for opening and closing the insertion opening particularly fast and thus allows for reducing the sample transfer time.

In another preferred embodiment of the present invention, the loading chamber is milled out of a solid block of high strength Aluminium alloy with a tensile strength>360 N/mm2 such as EN AW-7075, EN AW-2007, EN AW-2017.

In a further preferred embodiment of the present invention, a transfer rod or a vacuum sample transfer device, in particular an ultra-high vacuum transfer device, is attached to the second port. By means of a transfer rod, a sample inserted into the loading chamber from the insertion opening can easily be transferred to the analytic or preparation chamber attached to the first port of the loading chamber. With a vacuum sample transfer device attached to the second port, a sample can be transferred from vacuum or from air. Indeed, a vacuum transfer device, such as an ultra-high vacuum transfer device known from the international patent application WO2020119956A1, comprises itself a transfer rod. The latter can thus be used to transfer a sample inserted into the loading chamber of the interfacing device through the insertion opening into the analytic chamber or from the vacuum device.

In another preferred embodiment of the present invention, the interfacing device comprises a vacuum gauge attached to a third port of the loading chamber. With the vacuum gauge, it is possible to monitor the vacuum level inside the loading chamber and to determine at which moment the vacuum level is sufficient for transferring a sample to the analytic chamber or to the vacuum transfer device.

In another preferred embodiment of the present invention, the interfacing device comprises a sample storage device attached to a fourth port of the loading chamber.

In another preferred embodiment of the present invention, the sample storage device is mounted on a linear feedthrough in order to switch in between different samples. This allows for loading/unloading samples into the analytic or preparation device without the need to vent the loading chamber every time. In yet another preferred embodiment of the present invention, the pumping port and/or the venting port of the gate valve are controlled by solenoid valves. By this, it is possible to automatically control the opening of the valves and to automate the transfer of a sample.

In a further preferred embodiment of the present invention, the loading chamber is box-shaped and wherein the first and second ports are placed on the two largest faces of the loading chamber and the insertion opening is the size of another face of the loading chamber. This allows for minimizing the volume of the loading chamber, and thus the pumping time and the transfer time, while allowing to have sufficiently access to the inside to the loading chamber in order to conveniently mount a sample onto a recipient. This is advantageous since the mounting time shall be as well as short as possible in order to reduce the transfer time.

In yet a further preferred embodiment of the present invention, the box shaped chamber in addition to the first and the second ports comprises a third and a fourth port on the two smallest faces of the loading chamber.

In another preferred embodiment of the present invention, the first, the second, the third and/or the fourth ports are in the form of insets with sealing faces directly machined in the external surface of the loading chamber. This allows for further reducing the volume of the loading chamber and the evacuation time required to bring the vacuum level of the loading chamber.

In another preferred embodiment of the present invention, the first port and/or the second port comprise bulkhead clamps, wherein the bulkhead head clamps comprise a first halve and a second halve and wherein the first halve and the second halve are rotatably attached to the loading chamber. This allows for a quick and simple attachment of the interfacing device to the analytic chamber and/or of the transfer device to the second port and thus for reducing the overall transfer time, for instance in the case of the transfer from a vacuum transfer device to an analytic chamber or from atmospheric pressure to a vacuum transfer device.

In a further preferred embodiment of the present invention, the first port and/or the second port further comprise T-shaped bolts for redirecting the radial forces produced by the bulkhead clamps when closed to an axial direction towards the sealing surface of the corresponding port. This ensures enough pressing force to deform an O-ring gasket.

In yet a further preferred embodiment of the present invention, the insertion opening comprises a V-shaped groove for accommodating the gasket, especially an elastomeric gasket. Thanks to the V-shaped groove, the gasket is securely positioned and cannot escape the groove when opening the insertion opening. Thus, it reduces the overall transfer time, since the gasket does need to be placed back in the groove after inserting the sample into the loading chamber.

In another preferred embodiment of the present invention, the closure element is a transparent lid, advantageously a glass lid. This allows for having an optimal optical access to the sample placed inside the loading chamber and thus for an easy and quick transfer of the sample.

In yet another preferred embodiment of the present invention, the insertion opening is closed by a container according to the present invention. By this means it is possible to rapidly and reliably transfer a sample kept in an inert gas atmosphere or under vacuum conditions to an analytic chamber and/or to a vacuum transfer device.

In a further preferred embodiment of the present invention, the interfacing device comprises a positioning mechanism for adjusting the relative position of a transfer device attached to the second port with respects to the loading chamber. This allows not only for exactly but also for quickly aligning the transfer device with the loading chamber. The time required for aligning the transfer device to the loading chamber can thus be reduced and with this the overall transfer time.

In yet a further preferred embodiment of the present invention, the positioning mechanism allows for positioning a transfer device along two, advantageously three, distinct directions with respects to the loading chamber. With this the alignment can be made more precisely and more quickly, reducing therefore the transfer time and the risk of sample contamination.

In another preferred embodiment of the present invention, the positioning mechanism comprises two rails for the translation of the transfer device along a translation direction towards the loading chamber and a transfer device lifting platform for moving the transfer device along one, advantageously two, direction, perpendicular to the translation direction. This allows for a rapid and reliable attachment of the transfer device to the loading chamber of the interfacing device.

According to a second aspect of the present invention, the goals of the present invention are achieved by means of a container for transporting a sample under vacuum or inert gas atmosphere, comprising a transport chamber, wherein the transport chamber comprises a container closure element removable from the transport chamber, a sample holder lifting platform, wherein the closure element and the lifting platform allow for hermetically sealing the transport chamber, and wherein the container comprises a lifting mechanism for moving the lifting platform and a sample holder with respects to the transport chamber allowing for having access to a sample mounted onto the sample holder. With such a container it is possible to transport a sample in an inert gas atmosphere or under vacuum thus protecting it from deterioration due to contact with corrosive gas like oxygen. The arrangement of the inventive container allows for a rapid and simple insertion of the sample inside the transport chamber. Furthermore, thanks to the lifting platform and the lifting mechanism it is possible to transfer the sample from the container to an interfacing device, such as the interfacing device according to the present invention, for its insertion into an analytic chamber. Furthermore, the fact that the closure element is removably attached to the transport chamber, advantageously by screws, is favourable since the closure element can be chosen dependent on the application required. The closure element can be chosen for the transport of a sample under moderate vacuum or moderate degree of purity of the inert gas or chosen to reach high-vacuum or high purity of the inert gas atmosphere. The closure element can furthermore be chosen to enable the cooling of the sample to cryogenic temperatures, which is important for the transport of vitrified biologic samples from a sample preparation station to an analytic device, such as a transmission electron microscope.

In a preferred embodiment of the second aspect of the present invention, the container comprises a closure flange for sealing the insertion opening of the loading chamber of an interfacing device according to the present invention. It allows for the attachment of the container to the loading chamber of the interfacing device according to the present invention and thus to the rapid and reliable transfer of a sample kept in an inert gas atmosphere inside the container to a analytic chamber and/or to a vacuum transfer device.

In another preferred embodiment, the container comprises a unidirectional valve for evacuating the transport chamber. This is particularly advantageous, since the transport chamber can be evacuated through the interfacing device on which it is mounted for sample transfer.

In a further preferred embodiment, the unidirectional valve is positioned such that the transport chamber and the loading chamber of the interfacing device according to the present invention can be evacuated by the same pumping system when the container is used to seal the insertion opening of the interfacing device according to the present invention.

In another preferred embodiment, the container comprises a non-evaporable getter pump attached to the transport chamber and/or a non-evaporable getter element inside the transport chamber. This allows for ensuring that the level of contamination inside the transport chamber is as low as possible.

In another preferred embodiment, the container comprises a vacuum gauge. With the vacuum gauge the vacuum level inside the transport chamber can be monitored.

In a further preferred embodiment, the container closure element is a transparent lid. This allows for an optimal optical access to the inside of the transport chamber and thus to a sample kept inside the latter.

In yet another preferred embodiment, the container closure element and the lifting platform are connected by at least one ultra-high vacuum compatible welded bellows. This allows for reaching high-vacuum conditions, i.e. 10⁻⁹ mbar, and high degree of purity of the inert gas atmosphere of the order of <1 ppm.

In another preferred embodiment, the container further comprises a cooling mean thermally connected to the sample holder by means of cooling ducts, wherein the cooling ducts are at least partially placed inside the welded bellow. By this, a sample can be kept at cryogenic temperature while ensuring that the level of contamination inside the transport chamber can be kept as low as <1 ppm.

In another preferred embodiment, the cooling mean is a liquid nitrogen Dewar or a mechanical cooler, such as a Stirling cooler or a Gifford-McMahon cooler. A liquid nitrogen Dewar has the advantage of the simplicity of its operation, but it requires a source of liquid nitrogen, which is difficult to have at hand when transporting a sample over large distances. A mechanical cooler can therefore be advantageous since it is independent of a source of cryogenic fluid and be operated by a battery. Furthermore, the mechanical cooler can be arranged such that it is powered by the 12V connection of a car.

In a further preferred embodiment, the container further comprises a cold block placed between and in thermal contact with the cooling ducts and the sample holder and a thermal shield in thermal contact with the cooling ducts, wherein the thermal shield is surrounding the sample holder and wherein the thermal contact between the cold block and the sample holder is arranged such that the sample holder is kept at a higher temperature than the temperature of the thermal shield when the cold block is at a temperature lower than room temperature.

In yet another preferred embodiment, the container comprises a temperature sensor attached to the sample holder. This allows for monitoring the temperature of the sample holder and thus of a sample mounted onto the sample holder.

### BRIEF DESCRIPTION OF THE DRAWINGS

FIG. 1 shows a first perspective view of an interfacing device according to a first embodiment of the present invention;

IG. 2 shows a second perspective view of an interfacing device according to a first embodiment of the present invention;

FIG. 3 shows the interfacing device of FIGS. 1 and 2 with a positioning mechanism for a sample transfer device;

FIG. 4 shows a perspective view of an interfacing device according to a second embodiment of the present invention with an ultra-high vacuum transfer device attached to it;

FIG. 5 shows a perspective view of a transport container according to a first embodiment of the present invention;

FIG. 6 shows a sectional view of the device of FIG. 5;

FIG. 7 shows a perspective view of a transport container according to a second embodiment of the present invention;

FIG. 7a shows device of FIG. 7 without the closure element;

FIG. 8 shows a sectional view of the device of FIG. 7 in the closed position;

FIG. 9 shows a sectional view of the device of FIG. 7 in the opened position;

FIG. 10 shows a sectional view of a transport container according to a third embodiment of the present invention in the closed position;

FIG. 11 shows a sectional view of a transport container according to the third embodiment of the present invention in the closed position;

FIG. 12 shows a sectional view of a transport container according to a fourth embodiment of the present invention in the closed position; and

FIG. 13 shows a sectional view of a transport container according to the fourth embodiment of the present invention in the closed position.

### DETAILED DESCRIPTION OF A PREFERRED EMBODIMENT

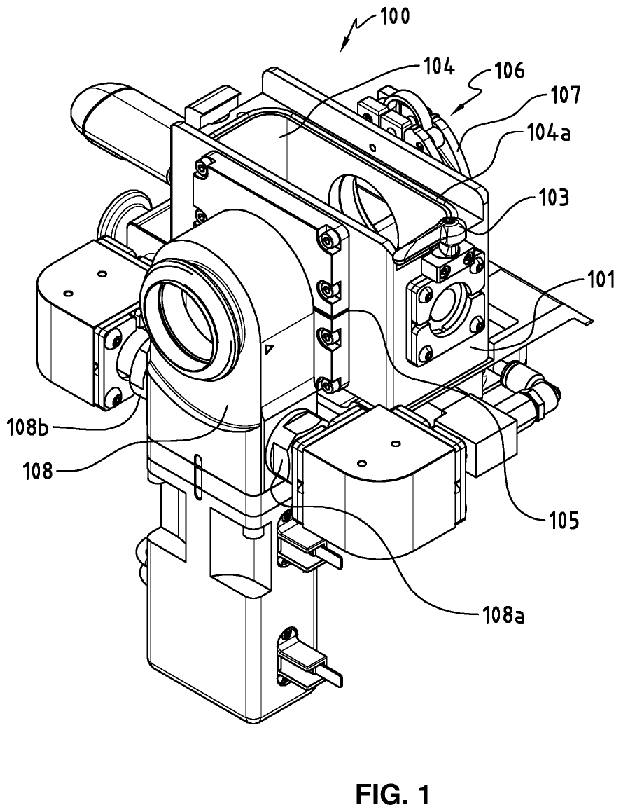

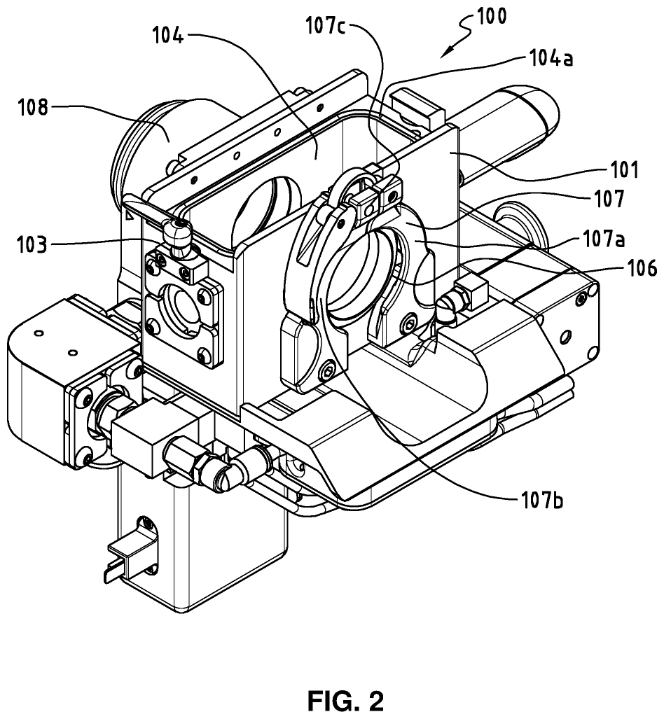

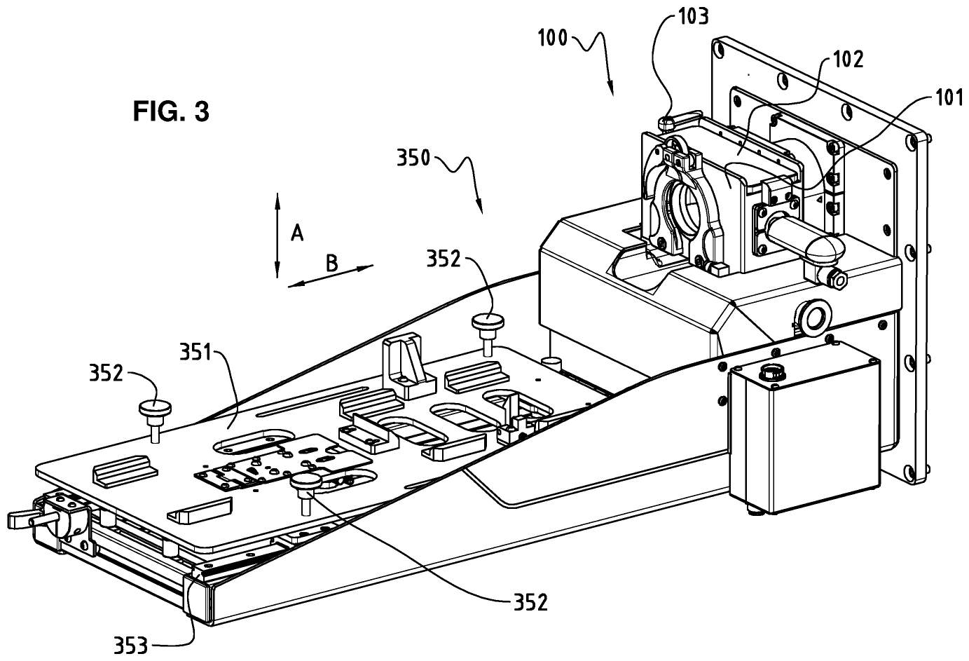

FIGS. 1 and 2 show a device 100 for interfacing a sample transfer device to an analytic or sample preparation chamber according to a preferred embodiment of the first aspect of the present invention. The device 100 comprises a box-shaped loading chamber 101 with transparent cover lid 102 (see FIG. 3) acting in this embodiment as a closure element for the loading chamber. By means of the quick-locking mechanism 103, the cover lid 102 can be released and remove from the insertion opening 104 of the loading chamber 101 to enable access to the inside of the latter. The quick-locking mechanism permits also to urge the cover lid against a gasket 104a in order to seal the loading chamber.

The device 100 comprises also a first port 105 for attaching the device to an analytic or preparation chamber and a second port 106 for attaching a transfer device. The latter can be for instance a transfer rod, a wobble stick, or a vacuum transfer device such a cryogenic ultra-high vacuum transfer device 200 as shown in FIG. 2.

In order to easily and quickly attach the transfer device 200 to the interfacing device 100, the second port 106 comprises a bulkhead clamp 107, wherein the bulkhead clamp features a first halve 107a and a second halve 107b rotatably attached to the loading chamber 101. Furthermore, the bulkhead clamp comprises T-shaped bolts (not shown) for securing the bulkhead clamps towards the loading 101 chamber when the clamp is closed. A spring loadable lever 107c permits to close the bulkhead clamp for attaching the transfer device.

On the opposite side of the loading chamber relative to the second port 106, a gate valve 108 is attached to the first port 105. The gate valve 108 comprises, as shown in FIG. 1, a pumping port 108a and a venting port 108b. Thanks to the integrations of the venting port and the pumping port in the gate valve itself, the volume of the loading chamber 101 can be kept as small as possible which is favourable in order to evacuate the loading chamber as quickly as possible by means of a pumping system attached to the pumping port 108a or by means of the vacuum system of the analytic or sample preparation chamber attached to the device 100. A quick evacuation is not only advantageous in order to reduce the overall workflow time for an experiment involving the transfer of a sample, it is also favourable in order to reduce the time that a sample is exposed to conditions in which it can easily be deteriorated.

By means of the removable cover lid 102 it is possible to have access to the inside of the loading chamber 101 and to mount a sample onto a sample holder or directly on a transfer device, for instance a transfer rod, for the transfer into the analytic or preparation device attached to the first port 105. As can be seen in FIGS. 1 and 2 the insertion opening 104, and thus the cover lid 102 is, in the present embodiment, as large as a complete face of the box-shape loading chamber 101. This permits not only to have an optimal optical access but also an optimal mechanical access into the inside of the loading chamber.

As illustrated in FIGS. 1 and 2, the first and second ports 105,106 are in the form of insets with sealing faces directly machined in the external surface of the loading chamber 101. This allows for reducing the volume of the device 100 and thus the time needed for evacuation.

As explained above, by removing the cover lid 102 it is possible to mount a sample on a dedicated sample holder for its transfer to an analytic or preparation chamber or for its transfer to a vacuum transfer device attached to the second port. In other words, thanks to the interfacing device 100, it is possible to transfer a sample into an analytic chamber from atmospheric conditions, i.e. through the insertion opening 104, or from vacuum with the help of a vacuum transfer device, for instance the device 200, attached to the second port 106. The interfacing device 100 is thus particularly advantageous in experimental workflows where a sample, not yet very delicate, must be inserted into a preparation chamber and later transferred under ultra-high vacuum conditions to an analytic chamber. Such an experimental workflow is, for instance, atom probe tomography (APT), which is a method of gaining information about the three-dimensional chemical composition on a molecular level. Meaningful APT experiments are strongly dependent on the environmentally controlled sample transfer between a dual beam Focused Ion Beam-Scanning Electron Microscopes (FIB-SEM) for the shaping of a sample to a sharp needle and an APT instrument for analysis.

To produce a needle-shaped sample, a standard lift out procedure in a FIB-SEM is used to cut out a bar in the region of interest from the bulk material of a sample, place it onto the needle holder and subsequently shape it to a sharp tip by ion beam milling. After the ion-milling process is finished, it is of outmost importance to avoid exposing the sample to atmospheric conditions as it would deteriorate it immediately. Thus, a vacuum, or even an ultra-high vacuum, transfer device is used to transfer the needle-shaped sample into an APT device.

Thanks to the interfacing device according to the present invention, it is possible to introduce a sample kept at atmospheric conditions into the loading chamber 101, to transfer it quickly into a preparation chamber and to transfer it again into a vacuum transfer device for its later analysis by means of the analytic device. One of the most important advantages of the device according to the present invention is that it enables such an experimental workflow without needing two different interfacing devices dependent on if the sample has to be introduced from air or from vacuum.

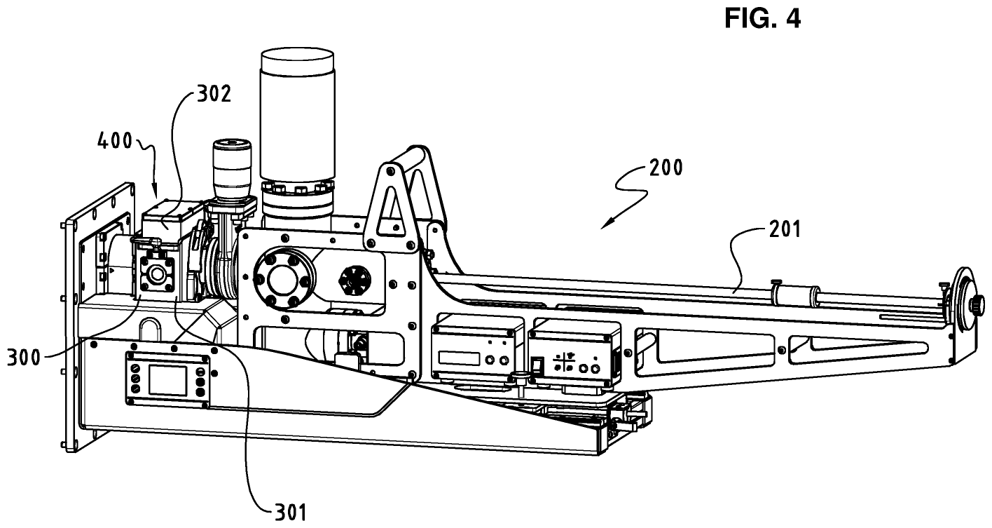

A second embodiment of an interfacing device 300 according to the first aspect of the present invention is presented in FIG. 4. The device 300 is identical to the device 100, but it comprises instead of the transparent lid 102 a closure element 302 in the form of a container 400 for transporting a sample in an inert gas atmosphere or in vacuum. The container 400 is removable from the insertion opening of the device 300 for the transport of a sample placed inside or for insertion of a sample directly into the loading chamber 301 of the device 300. It is important to note that the device 300 can be turned into a device 100 just by replacing the container 400 with a transparent lid 102.

In order to facilitate the attachment of a transfer device on the second port of the device 300, the latter comprises, as illustrated in FIG. 3, a positioning mechanism 350 for adjusting the relative position of the transfer device with respects to the loading chamber. Advantageously, the positioning mechanism 350 allows for positioning a transfer device along two, advantageously three, distinct directions with respects to the loading chamber. For that, the positioning mechanism 350 comprises a lifting plate 351 that can be moved with the lifting knobs 352. With the knobs 352 the lifting plate 351, and thus the transfer device mounted on it, can not only be translated along axis A, it can also be tilted with respects to the loading chamber 101. Furthermore, the lifting plate 351 is mounted on rails for translation along direction B.

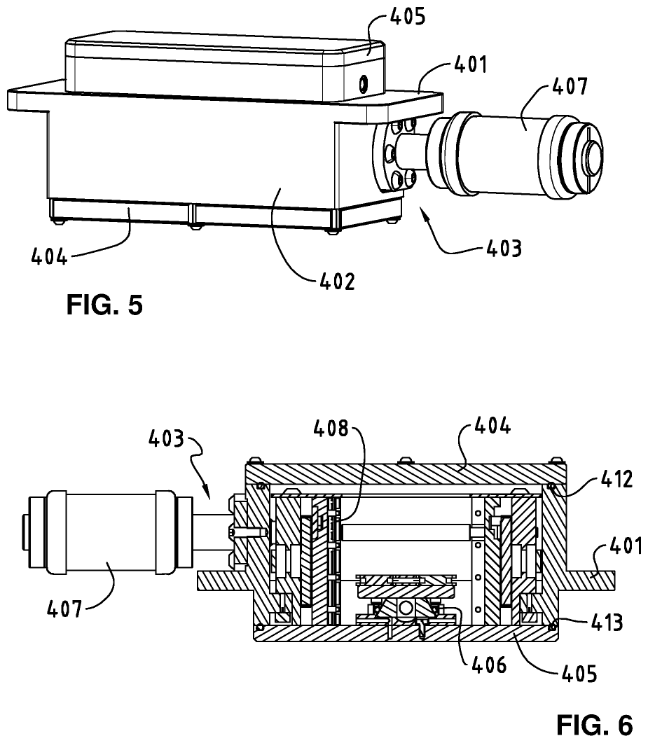

FIGS. 5 and 6 show a first embodiment of a container 400 for transporting a sample in an inert gas atmosphere or into vacuum according to the second aspect of the present invention. As can be seen in this figure, the container 400 comprises a closure flange 401 dimensioned such that by means of the container 400 and the quick-locking mechanism 103 of the device 300 the insertion opening of the interfacing device 100,300 can be sealed. The container 400 is an extremely compact sample transport module which can be introduced/extracted to/from an inert gas glove box through the glove boxes standard load lock and subsequently carried to any analytical instrument that is equipped with the interfacing device 100,300 where it is simply plugged in the insertion opening of the loading chamber of the device.

Compared to an ultra-high vacuum transfer device, the container 400 is a complementary way for sample transport under controlled environment. Being much more compact and lightweight than a sample transfer device such as an ultra-high vacuum sample transfer device 200 (see FIG. 1), its handling is extremely simple and the transfer time from one instrument to another can be considerably reduced. Furthermore, it is much more cost effective than an ultra-high vacuum transfer device. It is complementary in a way that its use may be limited to either samples that are apt to corrosion but maybe not extremely reactive or to workflow steps where samples are still in a “raw” state, for instance already mounted on a sample holder inside a glove box, maybe already vitrified but not yet cut and sliced by a FIB or shaped to an Atom Probe needle. Nevertheless, also these “raw” samples need to be kept under controlled conditions during sample transport.

A further advantage of the container 400 is the fact that samples can be transferred to an ultra-high vacuum transfer device and vice versa via the interfacing device 100,300. This enables the user to mount the sample to a sample holder in a standard glovebox without any customization. Subsequently he can take the container 400 out of the glove box through the load lock and transfer the sample to the ultra-high vacuum transfer device via any interfacing device 100,300 available.

Realistically the vacuum level inside the container 400 can be maintained in the range of 10⁻³ to 10⁻⁴ mbar without active pumping for several hours. However, a miniature Non-Evaporable Getter (NEG) pump can be added, for instance via an additional side port (not shown here). When actively pumped by a NEG, a vacuum level in the 10⁻⁶ mbar range or better can be achieved, allowing for transport of extremely reactive samples such alkali metals. Instead of a NEG pump attached to a port of the transport chamber 402, a NEG element 408 can be provided inside the transport 402. Electrical feedthroughs for the activation by a heating cycle of the NEG element can be provided on an extra port of the chamber 402. Furthermore, an auxiliary vacuum port (not shown here) can be provided to add a vacuum sensor.

When using the container 400 for sample transfer to an analytical or preparation instrument, a compatible docking system must be installed on the host instrument, such as the interfacing device 100,300. Once the container 400 is installed on the insertion opening of the interfacing device and the loading chamber evacuated, the transport chamber 401 of the container 400 can be opened by means of a lifting mechanism 403. Thanks to the lifting mechanism 403, the lifting platform 405 and with it the sample holder 406, can be moved, giving access to the sample holder. The lifting mechanism is arranged such that the sample holder can put on the translation axis of the transfer device attached to the first port of the interfacing device 100,300, as for instance the transfer rod 201 of the ultra-high vacuum transfer device 200 (see FIG. 4). The lifting mechanism can be actuated by hand by means of the rotary handle 407 or by means of a dedicated motor (not shown).

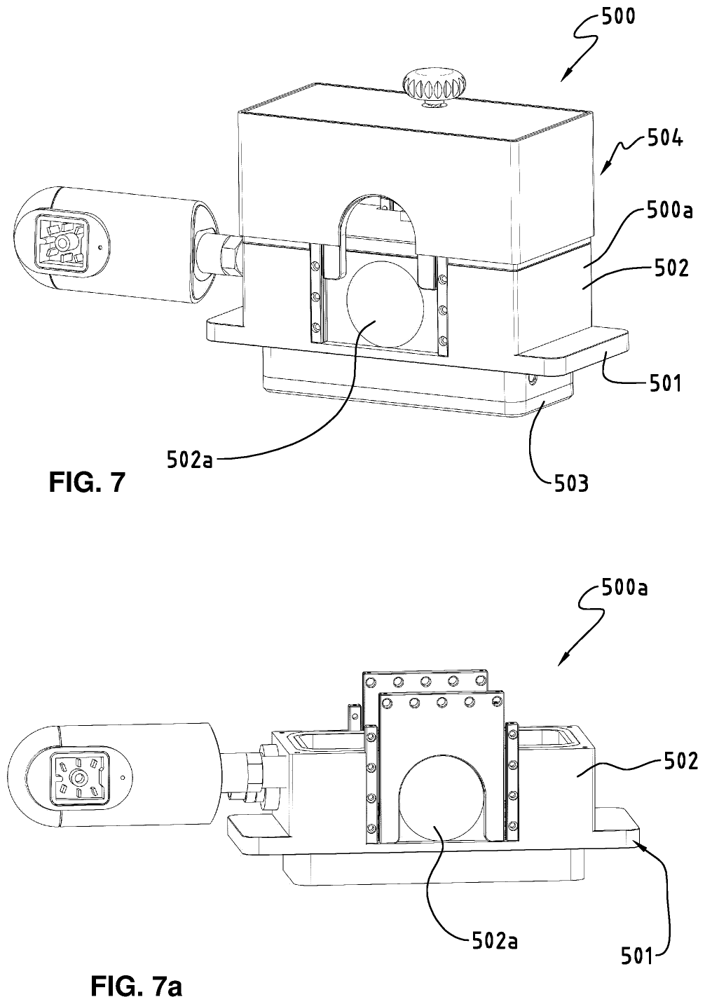

FIGS. 7 to 9 shows a container for transporting a sample under vacuum or inert gas atmosphere 500 according to a second embodiment of the second aspect of the present invention.

The container 500 comprises a base module 500a with a closure flange 501 dimensioned such that by means of the container 500 and the quick-locking mechanism 103 of the device 300 the insertion opening of the interfacing device 100,300 can be sealed. Container 500 comprises furthermore a window 502a for optical access into the transport chamber 502. The transport chamber can be sealed on one side with lifting platform 503 and on the other side by the closure element 504.

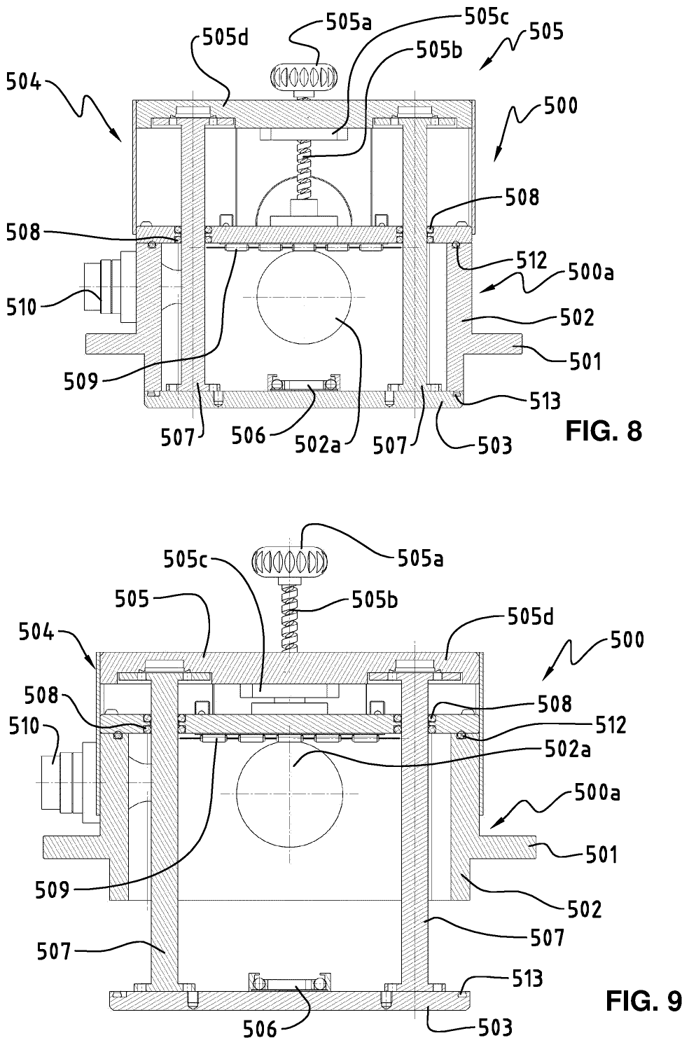

As best seen in FIGS. 8 and 9, container 500 comprises a lift mechanism 505, by means of which the lifting platform 503 with the sample holder 506 can be moved with respects to the transport chamber 502. By rotating the handle 505a, and thus the screw 505b, clockwise the plate 505c will move towards the transport chamber 502. As the top plate 505d of the lifting mechanism 505 is connected by means of the poles 507 to the lifting platform 503, the latter moves away from the transport chamber 502. By rotating the handle 505a anti-clockwise, the lifting platform 503 and the sample holder 506 move towards the transport chamber 502. The lifting mechanism is arranged such that the sample holder 506 can be brought on the translation axis of the transfer device attached to the interfacing device 100, 300, thus allowing the mounting of a sample on the sample holder 506 or the removal of a sample from this sample holder.

In order to maintain a certain degree of vacuum or a certain degree of purity of the inert gas atmosphere inside the transport chamber 502, sealing bearings 508 are arranged around the poles 507. Furthermore, NEG elements 509 are provided inside the chamber 502. Electrical feedthroughs 510 required for the operation of the non-evaporable elements are provided also.

The embodiment of a transport container presented in FIGS. 7 to 9 allows for the transport of a sample in an inert gas atmosphere of a purity of <1 ppm or in a vacuum of the order of 10⁻⁹ mbar.

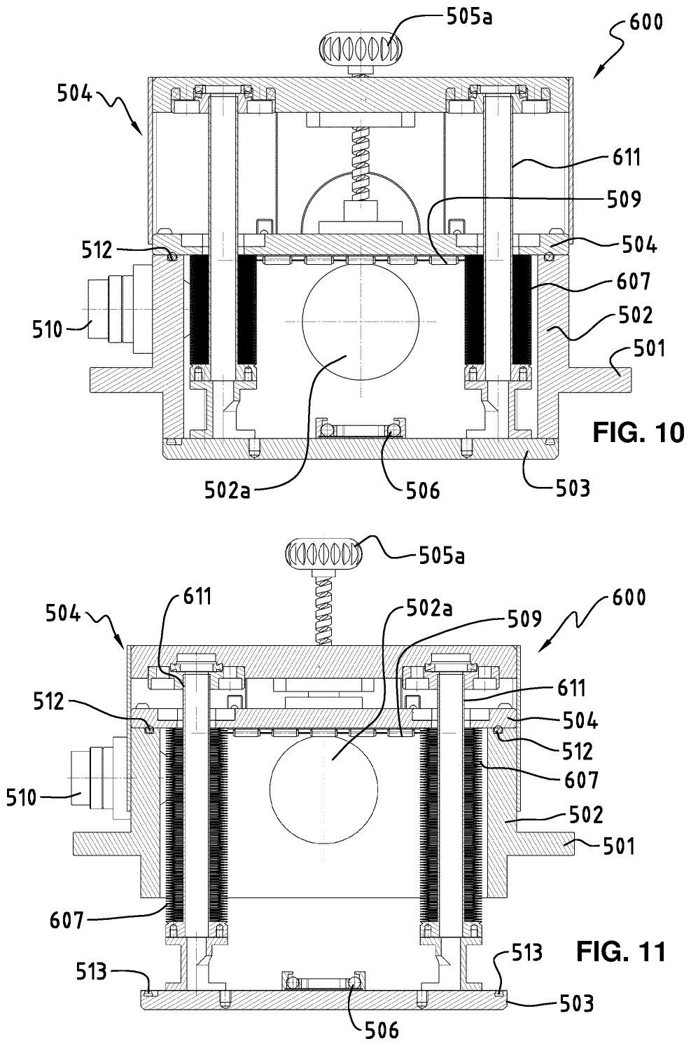

In order to transport very delicate sample, is it advantageous to provide a transport container that allows for maintaining a vacuum of the order of 10⁻⁹ mbar and/or a purity of the inert gas atmosphere of <1 ppm for at least 48 hours. Such a container 600 is presented in FIGS. 10 and 11. Container 600 is very similar to container 500 with the difference that poles 507 are replaced by welded bellows and that the bearings 509 are not present. The bellows allow for the movement of the lifting platform 503 with respect to the transport chamber 52 while ensuring an airtight connection with the enclosure element 504. In order to ensure that the lifting platform 503 undergoes a translation movement with respects to the chamber 502, the welded bellows are arranged around translation ducts 611.

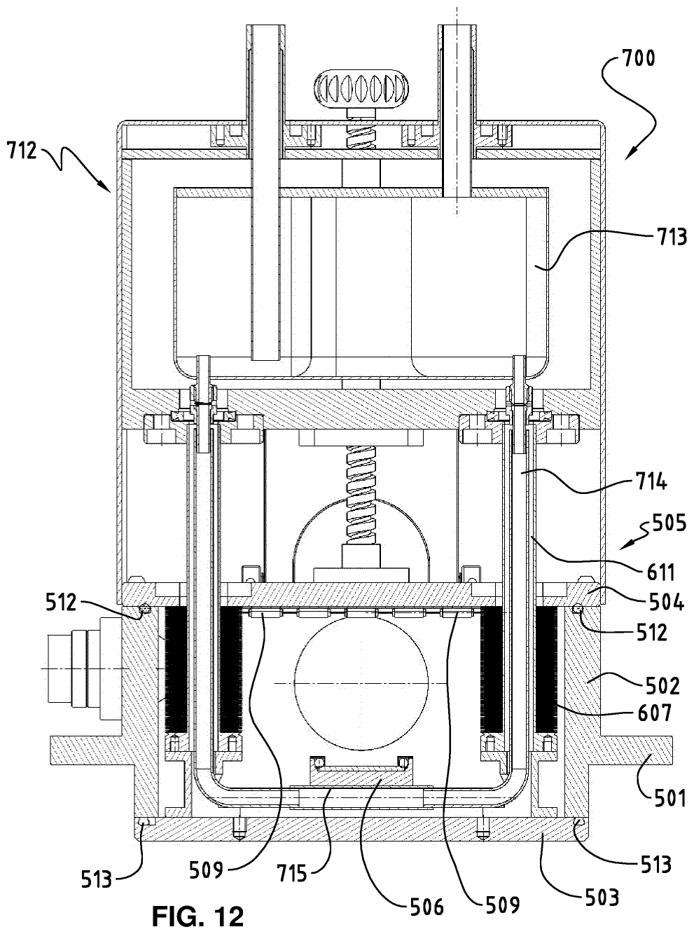

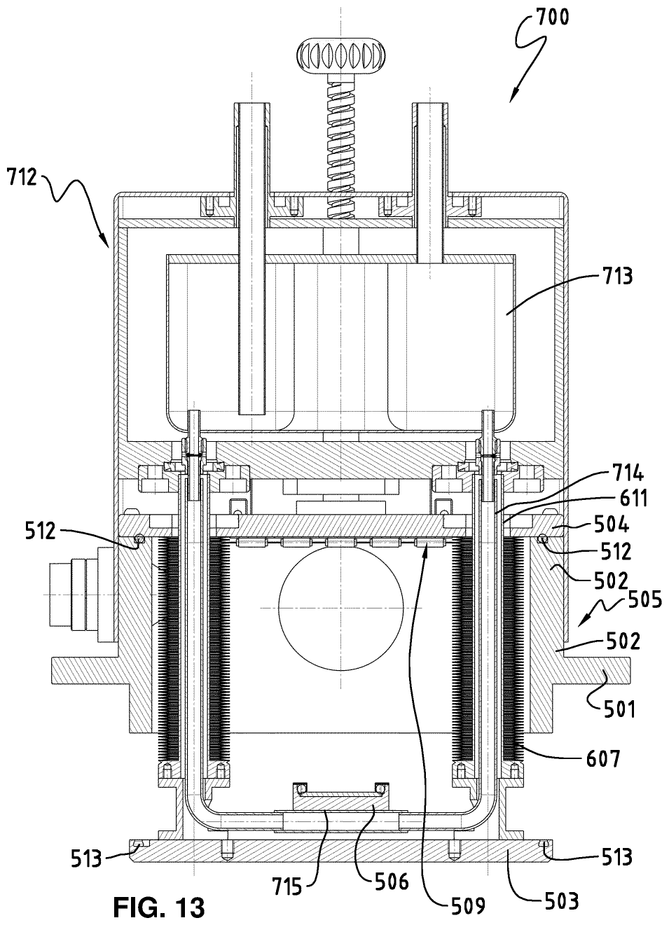

FIGS. 12 and 13 show a further embodiment of a transport container 700 for transporting a sample under vacuum or inert gas atmosphere and at cryogenic temperature. This particularly advantageous when transporting biological samples that have been shock frozen. The container 700 is very similar to the container 600 of FIGS. 10 and 11 with the difference that cooling means 712, in the form a liquid nitrogen Dewar 713, are provided. Dewar 713 is in thermal contact with the sample holder 506 by means of cooling ducts 714, advantageously positioned inside the translation ducts 611, thus allowing for the cooling of a sample mounted on the sample holder 506.

The thermal contact between the cooling ducts 714 and the sample holder 506 is advantageously made by means of a cooling block 715 attached to the ducts. This block is preferably made out of material with a high thermal conductance such as, copper or copper-beryllium.

Advantageously, the sample holder 506 could be surrounded by a thermal shield (not shown in the Figures) in thermal contact with the cooling ducts 714. Favourably, the thermal contact between the thermal block and the sample holder is arranged such that the temperature of thermal shield is lower than the temperature of the sample holder when the temperature of the latter is below room temperature. By this, one can guarantee that the sample is not the coldest element inside the transport chamber and thus ensure that the sample is not acting as cryogenic pump. It is important to note that the Dewar 713 could be replaced by a mechanical cooler, such as a Stirling cooler or a Gifford-McMahon cooler, and the cooling ducts by means of cooling rods.

In all embodiments 400, 500, 600 and 700, besides providing NEG elements, for maintaining high purity inside the chamber 502, a metallic gasket 412,512 is provided between the transport chamber and the closure element and an elastic metallic gasket 413,513, such as a metallic gasket composed of two metallic rings sandwiching a spring, is provided between the lifting platform and the transport chamber.

Finally, in all embodiments of the transport container according to the present invention, it is advantageous to provide for a unidirectional vale that allows for the pumping of the transport chamber. Favourably, the unidirectional valve is arranged such that when the container is placed on the insertion opening of the interfacing device according to the present invention, the transport chamber of the container can be evacuated by the sample pumping system as the loading chamber of the interfacing device.

1. Device for interfacing a sample transfer device to an analytic or sample preparation device comprising a loading chamber, wherein the loading chamber comprises a first port for attaching the device to the analytic device or the sample preparation device and a second port for attaching a sample transfer device, wherein the device comprises an insertion opening for inserting a sample kept under atmospheric condition into the loading chamber, a closure element removable from the insertion opening, wherein the insertion opening exhibits a quick-locking mechanism with which the insertion opening can be sealed with theclosure element, and a gate valve attached to the first port, wherein the gate valve comprises a pumping port for evacuating the loading chamber and a venting port for venting the loading chamber.

2. Device according to claim 1, wherein the quick-locking mechanism comprises a bulkhead rotating clamp with which the closure element can be pushed against a gasket of the insertion opening.

3. Device according to claim 1, wherein the loading chamber is milled out of a solid block of high strength Aluminium alloy with a tensile strength>360 N/mm².

4. Device according to claim 1, wherein a transfer rod or a vacuum sample transfer device, in particular an ultra-high vacuum transfer device, is attached to the second port.

5. Device according to claim 1 comprising a vacuum gauge attached to a third port of the loading chamber.

6. Device according to claim 1 comprising a sample storage device attached to a fourth port of the loading chamber.

7. Device according to claim 1, wherein the pumping port and/or the venting port of the gate valve are controlled by solenoid valves.

8. Device according to claim 1, wherein the loading chamber is box-shaped and wherein the first port and second port are placed on the two largest faces of the loading chamber andthe insertion opening is the size of another face of the loading chamber.

9. Device according to claim 1, wherein the first port, the second, a third, and/or a fourth port are in the form of insets with sealing faces directly machined in the external surface of the loading chamber.

10. Device according to claim 1, wherein the first port and/or the second port comprises bulkhead clamps, wherein the bulkhead head clamps comprise a first half and a second half and wherein the first half and the second half are rotatably attached to the loading chamber.

11. Device according to claim 10, wherein the first port and/or the second port further comprise T-shaped bolts for redirecting radial forces produced by the bulkhead clamps when closed to an axial direction towards a sealing surface of the corresponding port.

12. Device according to claim 1, wherein the insertion opening comprises a V-shaped groove for accommodating the gasket, especially an elastomeric gasket.

13. Device according to claim 1, wherein the closure element is a transparent lid, advantageously a glass lid.

14. Device according to claim 1, wherein the insertion opening is closed by the container according to claim 18.

15. Device according to claim 1 comprising a positioning mechanism for adjusting a relative position of a transfer device attached to the second port with respects to the loading chamber.

16. Device according to claim 15, wherein the positioning mechanism allows for positioning a transfer device along two, advantageously three, distinct directions with respects to the loading chamber.

17. Device according to claim 15, wherein the positioning mechanism comprises two rails for translation of the transfer device along a translation direction towards the loading chamber and a transfer device lifting platform for moving the transfer device along one, advantageously two, direction, perpendicular to the translation direction.

18. Container for transporting a sample under vacuum or inert gas atmosphere, comprising a transport chamber, wherein the transport chamber comprises a container closure element removable from the transport chamber, a sample holder lifting platform, wherein the closure element and the lifting platform allow for hermetically sealing the transport chamber, and wherein the container comprises a lifting mechanism for moving the lifting platform and a sample holder with respects to the transport chamber allowing for having access to a sample mounted onto the sample holder, the container further comprising a closure flange for sealing an insertion opening of a loading chamber of an interface device.

19. (canceled)

20. Container according to claim 18, comprising a unidirectional valve for evacuating the transport chamber.

21. Container according to claim 20, wherein the unidirectional valve is positioned such that the transport chamber can be pumped through the loading chamber of an interfacing device when the container is used to seal an insertion opening of the interfacing device.

22. Container according to claim 18, comprising a non-evaporable getter pump attached to the transport chamber and/or a non-evaporable getter element inside the transport chamber.

23. Container according to claim 18, comprising a vacuum gauge.

24. Container according to claim 18, wherein the container closure element is a transparent lid.

25. Container according to claim 18, wherein the container closure element and the lifting platform are connected by at least one ultra-high vacuum compatible welded bellows.

26. Container according to claim 25, wherein it comprises a cooling means thermally connected to the sample holder by cooling ducts, wherein the cooling ducts are at least partially placed inside the welded bellows.

27. Container according to claim 26, wherein the cooling means is a liquid nitrogen Dewar or a mechanical cooler, such as a Stirling cooler or a Gifford-McMahon cooler.

28. Container according to claim 26, further comprising a cold block placed between and in thermal contact with the cooling ducts and the sample holder and a thermal shield in thermal contact with the cooling ducts, wherein the thermal shield is surrounding the sample holder and wherein the thermal contact between the cold block and the sample holder is arranged such that the sample holder is kept at a higher temperature than the temperature of the thermal shield when the cold block is at a temperature lower than room temperature.

29. Container according to claim 26 comprising a temperature sensor attached to the sample holder.
